(19) United States
(12) Patent Application Publication
(10) Pub. No.: US 2007/0247260 A1
(43) Pub. Date: Oct. 25, 2007

(54) ELECTRONIC DEVICE

(75) Inventors: Naoko YANASE, Kanagawa-ken (JP); Takaaki YASUMOTO, Kanagawa-ken (JP); Ryoichi OHARA, Kanagawa-ken (JP); Kenya SANO, Kanagawa-ken (JP); Shingo MASUKO, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/739,396

(22) Filed: Apr. 24, 2007

(30) Foreign Application Priority Data
Apr. 25, 2006 (JP) 2006-120881

(51) Int. Cl. H03H 9/54; H03H 9/58

(52) U.S. Cl. 333/187; 333/189

(57) ABSTRACT

An electronic device includes: a substrate; a first film provided on a major surface of the substrate; and a crystalline second film covering at least a part of the end surface and provided on the first film and the substrate. The end surface has an inclined surface which is inclined to the major surface of the substrate. The inclined surface has a curved surface whose slope becomes gentle with getting closer to the substrate.

### CROSS-REFERENCE TO RELATED APPLICATIONS

This application is based upon and claims the benefit of priority from the prior Japanese Patent Application No.2006-120881, filed on Apr. 25, 2006; the entire contents of which are incorporated herein by reference.

### BACKGROUND OF THE INVENTION

1. Field of the Invention

This invention relates to an electronic device, and more particularly to electronic devices such as a thin film bulk acoustic resonator and a MEMS.

2. Background Art

In recent years, electronic devices, such as a MEMS (Micro Electro Mechanical System) device and a thin film bulk acoustic resonator (FBAR) which integrate an acceleration sensor or a pressure sensor on a silicon substrate, are developed and their practical applications are expected.

In these electronic devices, where a first film is provided on a major surface of a supporting substrate, furthermore a second film is provided so as to cover the supporting substrate and an end portion of the first film, the end portion of the first film being substantially perpendicular to the major surface of the supporting substrate lowers “step coverage”. Then, problems of cracks and subsidiary fractures in the second film are caused.

For example, for FBAR, a lower electrode is provided on the supporting substrate having a cavity and a piezoelectric film is provided on the electrode. However, cracks or subsidiary fractures at a step portion formed at the end of the lower electrode deteriorate a piezoelectric characteristic.

Contrary, it is disclosed that the end portion of the lower electrode is tapered and an angle between the tapered plane and the major surface of the supporting substrate is 5°˜30° (U.S. patent application Publication No. 2004/0263287A1).

However, after studies by present inventors, it is revealed that cracks or fractures have a propensity to be caused due to produced stresses in the second film formed over the lower end of the tapered plane where the tapered plane has a flat shape.

### SUMMARY OF THE INVENTION

According to an aspect of the invention, there is provided an electronic device including: a substrate; a first film provided on a major surface of the substrate and having at least one end surface; and a crystalline second film covering at least a part of the end surface and provided on the first film and the substrate, the end surface having an inclined surface which is inclined to the major surface of the substrate, and the inclined surface having a curved surface whose slope becomes gentle with getting closer to the substrate.

According to an aspect of the invention, there is provided an electronic device including: a substrate; a first film provided on a major surface of the substrate and having at least one end surface; a crystalline second film covering at least a part of the end surface and provided on the first film and the substrate; and an upper electrode provided on the second film, the end surface having an inclined surface which is inclined to the major surface of the substrate, and the inclined surface having a curved part at its upper end, a slope of the curved part being gentle with getting closer to the upper electrode.

According to an aspect of the invention, there is provided an electronic device including: a substrate; a first film provided on a major surface of the substrate and having at least one end surface; and a crystalline second film covering at least a part of the end surface and provided on the first film and the substrate, the end surface having an inclined surface which is inclined to the major surface of the substrate, and the inclined surface having a convex portion protruding toward the second film, the convex portion being provided between an upper end and lower end of the inclined surface.

### BRIEF DESCRIPTION OF THE DRAWINGS

FIG. 1 is a schematic cross section showing an electronic device according to a first embodiment of the invention.

FIG. 2A is a top view of the electronic device of the embodiment, and FIG. 2B is a bottom view thereof.

FIG. 3 is a schematic cross section showing a first specific example of the tapered portion in FIG. 1.

FIG. 4 is a schematic cross section showing a first comparative example of the tapered portion.

FIG. 5 is a schematic cross section showing a second specific example of the tapered portion.

FIG. 6 is a schematic cross section showing a third specific example of the tapered portion.

FIG. 7 is a schematic cross section showing a fourth specific example of the tapered portion.

FIG. 8 is a schematic cross section showing a second comparative example of the tapered portion.

FIG. 9 is a schematic diagram showing a process of manufacturing FBAR of the first embodiment.

FIG. 10 is a schematic diagram showing a process of manufacturing FBAR of the first embodiment.

FIG. 11 is a schematic cross section showing the tapered portion of FIG. 10.

FIG. 12 is a partial microstructure photograph showing the tapered portion of FIG. 11.

FIG. 13 is a schematic diagram showing a process of manufacturing FBAR of the first embodiment.

FIG. 14 is a schematic diagram showing a process of manufacturing FBAR of the first embodiment.

FIG. 15 is a partial microstructure photograph showing a part of FBAR of the first embodiment.

FIG. 16 is a schematic diagram showing a process of manufacturing FBAR of the first embodiment.

FIG. 17 is a schematic diagram showing a process of manufacturing FBAR of the first embodiment.

FIG. 18 is a schematic cross section showing a third comparative example of the tapered plane of the first embodiment.

FIG. 19 is a schematic cross section showing an electronic device according to a second embodiment of the invention.

FIG. 20 is a process cross section showing a process of manufacturing FBAR of the second embodiment.

FIG. 21 is a process cross section showing a process of manufacturing FBAR of the second embodiment.

FIG. 22 is a process cross section showing a process of manufacturing FBAR of the second embodiment.

FIG. 23 is a circuit diagram of a voltage control oscillator mounting the electronic device according to the embodiment.

FIG. 24 is a schematic diagram showing a mobile phone mounting the electronic device according to the embodiment.

### DETAILED DESCRIPTION OF THE INVENTION

Embodiments of the invention will now be described with reference to the drawings.

### A First Embodiment

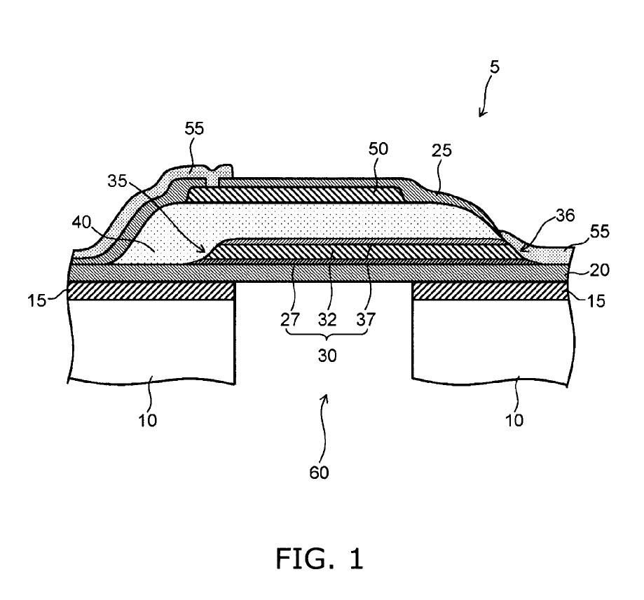

FIG. 1 is a schematic cross section showing an electronic device according to a first embodiment of the invention.

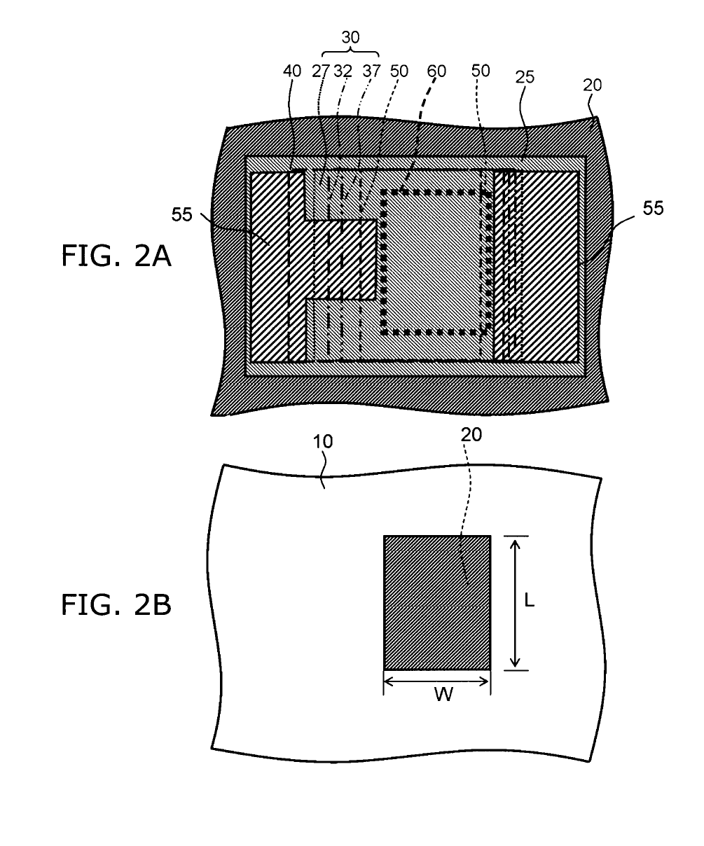

FIG. 2A is a top view of the electronic device of the embodiment, and FIG. 2B is a bottom view thereof.

In addition, in figures from FIG. 2, elements similar to those in figures as described before are marked with the same reference numerals and not described in detail.

An electronic device in the present embodiment is a thin film bulk acoustic resonator (FBAR) 5. The FBAR 5 is formed on a supporting substrate 10 comprising Si (silicon). The supporting substrate has a cavity portion 60. Furthermore, a thermal oxidation (SiO₂) film 15 and a lower passivation layer 20 comprising, for example, silicon nitride (SiN) film are provided in this order all over the supporting substrate 10. And a first film 30 having a stacked structure is formed on a main surface of the lower passivation layer 20. The stacked structure can be formed by providing an non-crystalline primary layer 27 comprising, for example, AI₀. 5Ta₀.₅, a lower electrode 32 comprising Al and an AIN film 37 comprising aluminum nitride (AIN) in this order. The crystal of the lower electrode 32 is oriented along the axis of (111), and that of AIN film 37 is oriented along the axis of (0001). A first tapered plane 35 and a second tapered plane 36 are provided respectively at the both end of the first film 30.

In the embodiment, lower portions of the first and the second tapered planes 35, 36 have a curved configuration so that a slope of the tapered plane becomes gentle with approaching the supporting substrate 10.

A second film 40 is provided on the first film 30 except the second tapered plane 36 and the lower passivation layer 20 on a side of the first tapered plane 35. The second film 40 is, for example, a piezoelectric film of AlN. Furthermore, the piezoelectric film is not limited to being made of AlN, but can be made of zinc oxide (ZnO) and lead zirconate titanate (PZT). An upper electrode 50 is provided on the piezoelectric film 40. The upper electrode 50 can illustratively be made of molybdenum (Mo). An upper passivation layer 25 is provided on the lower passivation layer 20, the piezoelectric film 40, the upper electrode 50 and the second tapered plane 36. An extracting electrode 55 comprising Al is provided on the upper passivation layer 25.

The upper electrode 50 and the lower electrode 32 are connected to the extracting electrode 55 and 55, respectively via a contact hole.

Furthermore, the cavity 60 is provided so that the FBAR 5 oscillating in a thickness direction does not touch the supporting substrate 10. The non-crystalline primary layer 27 and the AlN film 37 have a role to increase the degree of polycrystalline orientation of the piezoelectric film. The upper and lower passivation layers 20, 25 have a role to prevent the piezoelectric film 40 and the non-crystalline primary layer 27 from being oxidized by atmospheric gases and humidity.

The piezoelectric film of FBAR 5 expands and contracts in a direction of thickness on applying a voltage between the upper electrode 32 and the lower electrode 50. For the application of an alternative voltage, a vertical resonant oscillation in thickness is observed at a specified frequency. Moreover a resonant characteristic is obtained at a desired frequency by adjusting the film thickness of FBAR 5. For example, where the frequency of 2 GHz is a pass band, the film thickness of the piezoelectric film 40 is about 1.5˜2.0 micrometers, depending on quality of material and film thicknesses of the upper electrode 50 and the lower electrode 30. Film thicknesses of the upper electrode 50 and the lower electrode 30 are 0.2˜0.3 micrometers. Furthermore, film thicknesses of the upper and the lower passivation layer 20, 25 are about 0.1˜0.05 micrometers. Moreover, assuming that input and output impedances are, for example, 50 ohm, the shape of the cavity 60 can be a square or a rectangle with a length or width of about 100˜200 micrometers, respectively. In addition, in the embodiment in regards to the tapered plane, the passivation layer and the electrode and the like, those near to the supporting substrate 10 are “lower” and those far from it are “upper”.

Next, specific examples of the tapered portion will be described in detail.

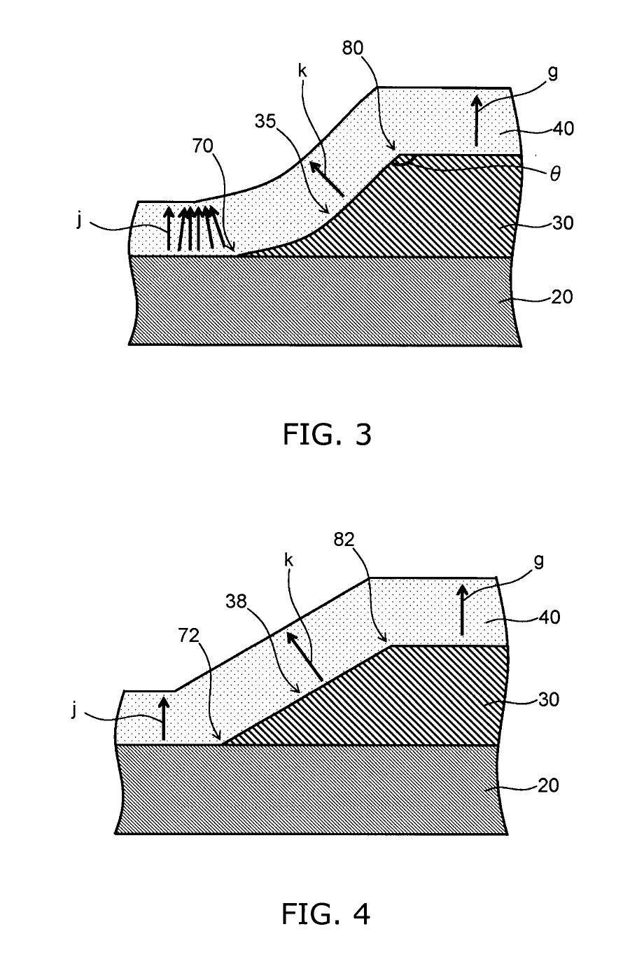

FIG. 3 is a schematic cross section showing a first specific example of the tapered portion in FIG. 1.

Moreover, FIG. 4 is a schematic cross section showing a first comparative example of the tapered portion.

In addition, the first film 30 will be described here as a single layer for simplicity.

First, the first comparative example will be described.

As shown in FIG. 4, in the comparative example, a first tapered plane 38 of the first film 30 has a planar shape. Moreover, an upper end 82 and a lower end 72 of the first tapered plane are not curved. If the piezoelectric film 40 is formed on the end portion of the first film 30 like this, “crack” and “fracture” are more likely to occur on the lower end 72 of the tapered plane 38. Here, a growth direction of the piezoelectric film 40 is substantially perpendicular to the main surface of the lower layer. That is to say, the growth direction (j) on the lower passivation layer 20 and the growth direction (k) on the first tapered plane 38 run into each other. Where growth directions of the first films 30 run into each other like this, cracks and fractures are likely to occur.

On the contrary, according to the first specific example, as shown in FIG. 3, the lower end 70 of the first tapered plane 35 is formed in the curved configuration so that the slope of the first tapered plane 35 becomes gentle with getting close to the supporting substrate 10. In other words, the first tapered plane 35 has a continuously curved smooth surface facing to the lower end. Therefore, the growth direction of the piezoelectric film 40 can be gradually changed near the lower end 70 as shown by an arrow in FIG. 3. In short, occurrence of cracks and fractures due to running into each other of two different growth directions each other (for example, j and k in FIG. 4) can be reduced. As a result, the dense and continuous piezoelectric film 40 can also be formed on the lower end 70. As a result of studies by the inventors, it is revealed that if a curvature radius on the first tapered plane 35 is larger than the thickness of the piezoelectric film formed on it, cracks and fractures of films due to running into each other of growth directions of the piezoelectric film 40 formed on it can be effectively suppressed, and the dense and continuous piezoelectric film 40 can be formed. That is to say, for the example shown in FIG. 3, it is advisable that the curvature radius of the first tapered plane 35 is larger than the thickness of the piezoelectric film 40, on any place of the first tapered plane 35, although it changes on every place.

On the other hand, the growth direction (g) on the first film 30 and the growth direction (k) on the first tapered plane 35 do not run into each other near the upper end 80 of the first tapered plane 35 and film growth is made while expanding. That is to say, the upper portion (k) of the first tapered plane 35 and the upper portion (g) of the first film 30 grow while filling spacing of the growth directions, the continuous and dense films are easy to be formed between those. Studies by inventors indicate that where the angle θ of the end portion 80 is approximately larger than 135°, it is easy to form the continuous and dense piezoelectric film 40 on it.

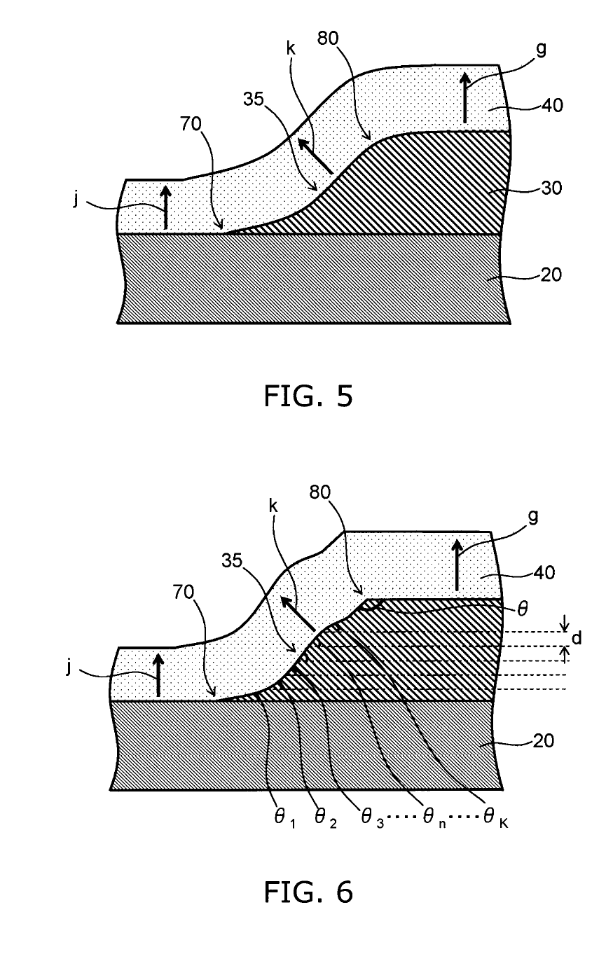

Next, FIG. 5 is a schematic cross section showing a second specific example of the tapered portion.

In the specific example, the curved configuration is also provided on the upper end 80 of the first tapered plane 35, which the slope of the first tapered plane 35 becomes gentle with getting close to the upper electrode 50. In this manner, it is possible to suppress a sharp change of the growth direction of the piezoelectric film 40 on the upper end 80 and form a more dense and continuous piezoelectric film 40.

FIG. 6 is a schematic cross section showing a third specific example of the tapered portion.

In the specific example, a convex portion toward to the piezoelectric film 40 is provided in an intermediate region of the first tapered plane 35.

In other word, the first tapered plane 35 is partitioned off parallel to the lower passivation layer 20. Angles (θ₁, θ₂, . . . θₖ) between each parallel line and the first tapered plane 35 are measured. These angles θ₁, θ₂, . . . θₖ (k is positive integer) are taken as a function of k. Here, θk has at least one relative maximum, and the angle increases from θ₁ to θₙ (θ_{1<θ}₂< . . . <θₙ) in this order in the downside lower than the portion giving the relative maximum value θⁿ.

Providing the relative maximum value on like this makes the slope gentle with getting close to the lower end 70 of the first tapered plane 35. Therefore, growth directions of the piezoelectric film 40 come to experience no running into each other on the lower end 70, and cracks and fractures of the piezoelectric film 40 can be suppressed. On the other hand, as growth directions of the piezoelectric film 40 distribute in diverging directions but not in directions running into each other near the relative maximum value θₙ, cracks and fractures and the like do not occur. Moreover, θₖ changes so as to increase gradually with getting close to the upper end 80 and thereafter to decrease again in the upper side higher than the portion giving the relative maximum value θₙ, therefore the occurrence of cracks and fractures due to running into each other of growth directions of the piezoelectric film 40 can be suppressed.

The structure providing the relative maximum value of θₖ in the intermediate region of the tapered plane like this is effective for the case and so on with the thick first film 30.

Furthermore, in the specific example, providing the convex portion in the intermediate region of the first tapered plane 35 makes it easy to increase the angle at the upper end 80 of the first tapered plane 35. That is to say, as described previously in FIG. 3, it becomes easy to increase the angle θ at the upper end 80 larger than 135°, and then the piezoelectric film 40 without cracks and fractures can be formed on the upper end portion 80, too.

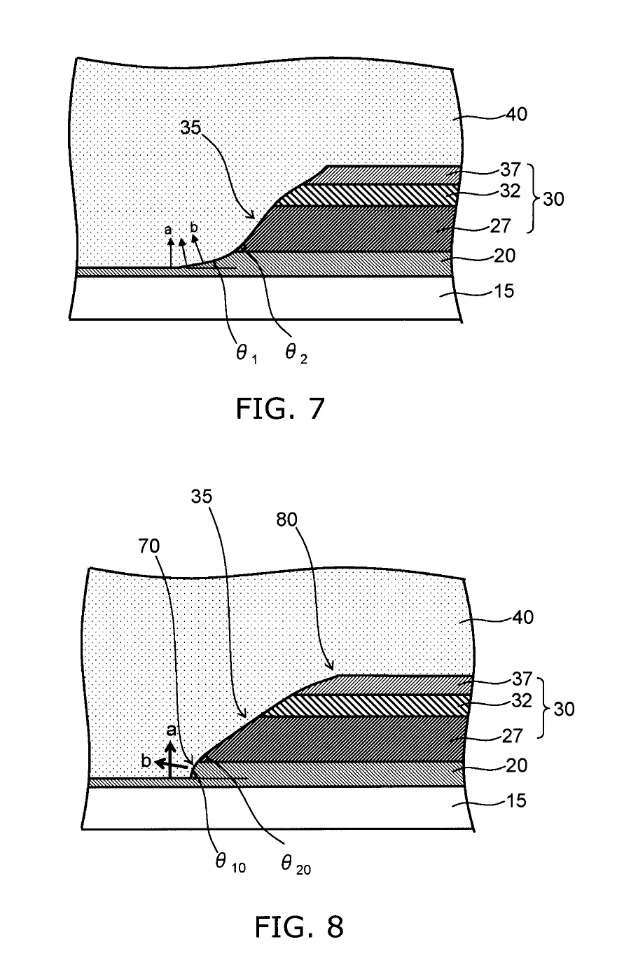

FIG. 7 is a cross section of the third specific example to which a film configuration of real FBAR is applied.

Moreover, FIG. 8 is a schematic cross section showing a second comparative example of the tapered portion.

The film configurations of the specific example and the comparative example are the same as those described previously in FIG. 1, and have the structure which the lower passivation layer 20 is stacked on a thermal oxidation film 15 and over it the non-crystalline primary layer 27, the lower electrode 32 and the AlN film 37 are stacked in this order. In any of these instances, the first tapered plane 35 is formed from the intermediate to the upper region of the lower passivation layer 20.

First, the comparative example will be described.

Here, an angle of the portion of the lower passivation layer 20 in the first tapered plane 35 is taken as θ₁₀. Moreover, an angle of the portion of the non-crystalline primary layer 27 provided on the lower passivation layer 20 is taken as θ₂₀.

As shown in FIG. 8, the comparative example has a structure with θ₁₀, larger than θ₂₀ (θ₁₀>θ₂₀). Where θ₁₀ and θ₂₀ are in the relation like this, θ₁₀ becomes inevitably large. Therefore, as shown by arrow marks a and b in FIG. 8, the piezoelectric film 40 grows while the portion (arrow a) on the major surface of the lower passivation layer 20 and the nearby portion (arrow b) of the first tapered plane 35 are running into each other. As a consequence, cracks and fractures become to be likely to occur at the lower end of the first tapered plane 35.

On the contrary, in the specific example, as shown in FIG. 7, the angle θ₁ of the lower passivation layer 20 of the first tapered plane 35 is smaller than the angle θ₂ of the non-crystalline primary layer 27 (θ₁<θ₂). In other word, θ₁ becomes inevitably small. In this manner, it is possible to change gradually growth directions of the piezoelectric film 40 between the portion (arrow a) on the major surface of the lower passivation layer 20 and the nearby portion (arrow b) of the first tapered plane 35. As a consequence, the growth directions become hard to run into each other and the piezoelectric film 40 without cracks and fractures is obtained.

Next, a relevant part of a method of manufacturing an electronic device according to the embodiment will be described.

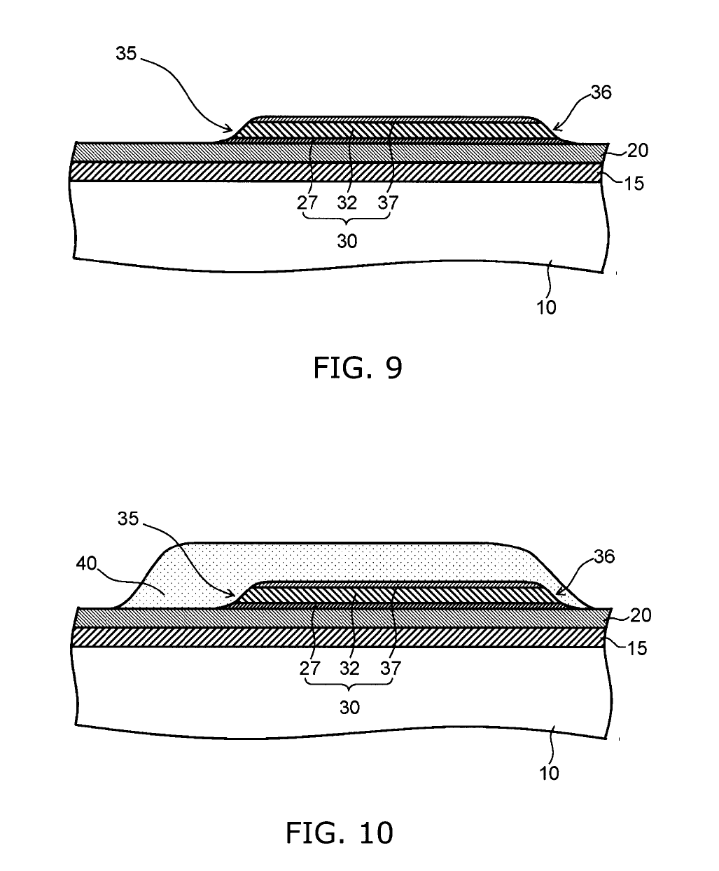

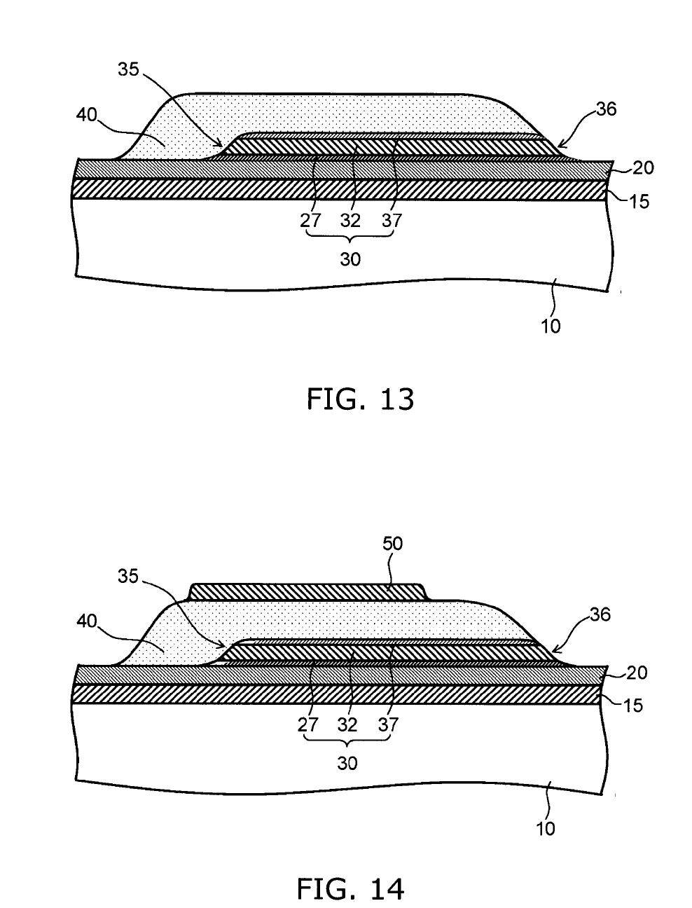

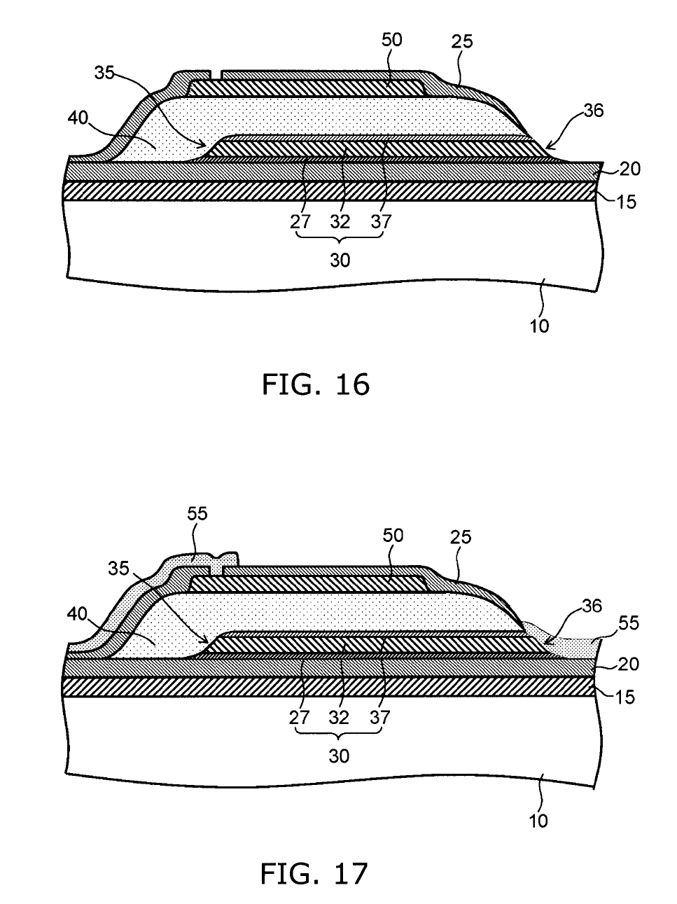

FIG. 9, FIG. 10, FIG. 13, FIG. 14, FIG. 16 and FIG. 17 are process cross sections showing a process of manufacturing the electronic device according to the embodiment. In addition, the electronic device is FBAR 5.

First, as shown in FIG. 9, a thermal oxidation film 15 of SiO₂ having a film thickness of about 500 nanometers on a supporting substrate 10 of Si having a substrate thickness of about 600 micrometers. A lower passivation layer 20 of SiN having a film thickness of about 50 nanometers is formed on the thermal oxidation film 15 using a plasma CVD (Chemical Vapor Deposition) method. A non-crystalline primary layer 27 of Al_{0.5}Ta_{0.5} having a film thickness of, for example, 10 nanometers is deposited on the lower passivation layer 20 using a sputtering method. A lower electrode 32 of Al having a film thickness of, for example, about 200 nanometers is deposited on the non-crystalline primary layer 27. Furthermore, an AlN film 37 having a film thickness of 30 nanometers is deposited on the lower electrode 32. Then, after patterning of a resist mask using photolithography, etching is performed so as to be a trapezoid narrowing in a direction facing the supporting substrate 10 using an RIE (Reactive Ion Etching) method. As a result, a first and a second tapered plane 35, 36 are obtained at both end portions of a first film 30.

Here, a method of manufacturing the first and the second tapered planes 35, 36 will be described below.

First, the trapezoidal resist mask being in a tapered configuration at both ends is provided on the first film. For example, a desired configuration is obtained by heating the resist to 150˜200° C. in an oven or on a hot plate after development. After that, etching is performed by the RIE method. Then, the first and the second tapered planes 35, 36 of the resist mask are transferred to the first film 30. In this manner, the first and the second tapered planes 35, 36 can be formed at both end portions of the first film 30. Moreover, in the embodiment, the first and the second tapered planes 35, 36 are formed in the configuration described previously in FIG. 3, FIG. 5 and FIG. 6.

The tapered angle of the first film 30 depends on a ratio of etching rates for the first film 30 and the resist mask. The resist mask having an etching rate, for example twice higher than that for the first film 30 is used. As a result, the tapered angle of the first film 30 can be reduced to about one-half of that of the resist mask. In the RIE method, for example a mixed gas with further addition of oxygen gas (θ₂) after diluting chlorine gas (Cl₂) and boron trichloride (BCl₃) gas with argon gas (Ar) can be used.

Next, as shown in FIG. 10, a piezoelectric film 40 having a film thickness of 1.7 micrometers is deposited all over the device comprising the lower passivation layer 20 and the first film 30 using the sputtering method.

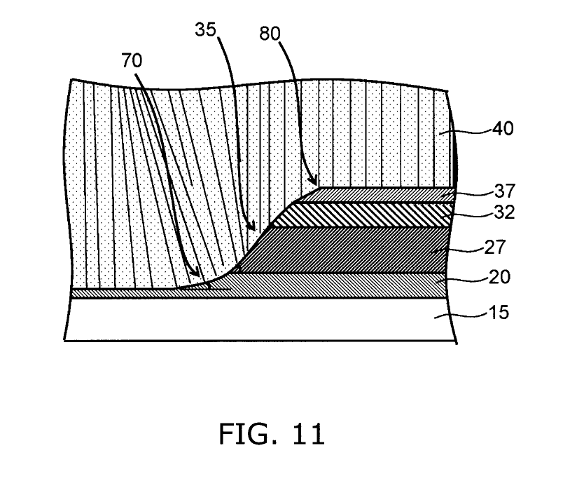

FIG. 11 is a schematic cross section showing the tapered portion of FIG. 10.

Directions of slanting lines described in the piezoelectric film 40 indicate growth directions of a polycrystalline AlN film. The lower portion 70 of the first tapered plane 35 has a curved configuration which the slope becomes small with getting close to the lower passivation layer 20.

Angles between each layer and the tapered plane 35 are, for example, 11° for the lower passivation layer 20, 14° for the non-crystalline primary layer 27, 18° for the lower electrode 32 and 6° for the AlN film 37. Moreover, it is known that the angle for the lower electrode 32 is the maximum value. These angles increase from the lower passivation layer 20 toward the lower electrode 32. This can suppress cracks and fractures of the piezoelectric film 40 on the lower end 70.

Moreover, the upper end 80 of the first tapered plane 35 also has a curved configuration which the slope is decreasing toward the upper electrode direction. The angle for the upper end is 174°. As the angle for the lower electrode 32 is larger than those for the AlN film 37 and the non-crystalline primary layer 27, the convex configuration is formed toward the piezoelectric film 40 between the upper end 80 and the lower end 70. The configuration can increase the angle for the upper end 80 of the first tapered plane 35. Therefore, cracks and fractures in the piezoelectric film 40 formed on the upper end 80 become to be hard to occur.

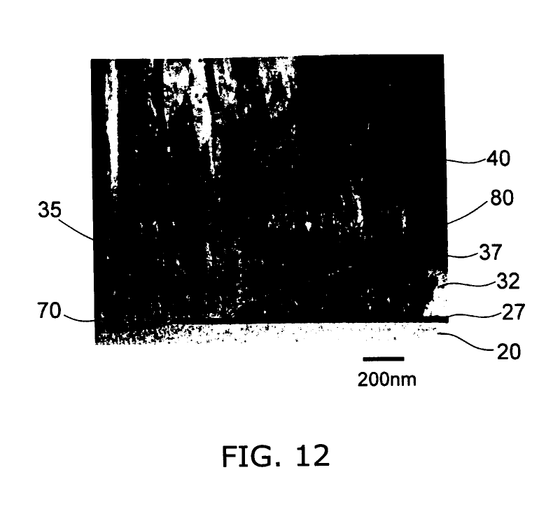

FIG. 12 is a TEM (Transmission Electron Microscopy) observation image showing the tapered portion of FIG. 10.

According to the embodiment, no cracks and fractures in the piezoelectric film 40 on the lower end 70 and the upper end 80 are also confirmed. As for crystalline orientation of the piezoelectric film 40 located over the lower electrode 30, characterization was performed via calculation of a half width of a rocking curve obtained for an AlN (0001) axis using an X-ray diffraction method. As a result, it was confirmed that the half width for the piezoelectric film 40 is 1.14° and the film has high crystalline orientation. The reason that such a highly oriented piezoelectric film 40 is obtained is that the first film 30 in the first embodiment comprises the three layers structure made of the non-crystalline primary layer 27, the lower electrode 32 and the AlN film 37. The lower electrode 32 on the non-crystalline primary layer 27 is highly oriented along the (111) axis and the AlN film 37 on it is also highly oriented along the (0001) axis. The orientation half width for the AlN film (0001) strongly affects resonant characteristics in a vertical thickness, and for AlN with a small half width, FBAR 5 having an excellent resonant characteristics (electric mechanical coupling coefficient kt² and Q value) can be obtained. Moreover, a small electric resistance of the lower electrode 32 allows the electrode to be thin. Consequently, a ratio of the piezoelectric film 40 in FBAR 5 can be increased. This results in sufficient use of the excellent AlN piezoelectric characteristic. However, in order to fabricate a multilayered film in which each film has a different etching rate for chlorine gas into a configuration with a smooth and gentle slope, addition of O₂ gas to the etching gas or excessive dilution of Cl₂ gas (about 1/100 for Ar gas) is required. Then, it becomes difficult to optimize the etching condition in comparison with etching of a normal single film.

Furthermore, in the embodiment, the relative minimum value of Rmin of the curvature of the tapered plane 35 is 2.1 micrometers. This is larger than 1.71 micrometers in the film thickness of the piezoelectric film 40. Therefore, as described previously in FIG. 3, no cracks and fractures occur in the piezoelectric film 40.

According to the embodiment like this, the first film 30 has a structure which suppresses cracks and fractures in the piezoelectric film 40 stacked on the first tapered plane 35.

Subsequently, as shown in FIG. 13, patterning of a resist mask is performed by photolithography. Then, the piezoelectric film 40 which is deposited on the second tapered plane 36, the lower passivation layer 20 of the second tapered plane 36 and the lower passivation layer 20 of the piezoelectric film 40 on the first tapered plane 35 is removed by the RIE method.

Next, as shown in FIG. 14, the upper electrode 50 is formed so as to sandwich the piezoelectric film 40 between the first film 30 and the upper electrode 50. The Mo film 50 with a film thickness of 300 nanometers is deposited using the sputtering method. Then, patterning of the resist mask is performed by photolithography. After that, the second electrode 50 is formed using a method of CDE (Chemical Dry Etching). At this time, a mixed gas of carbon fluoride (for example, CF₄) and O₂ may be used.

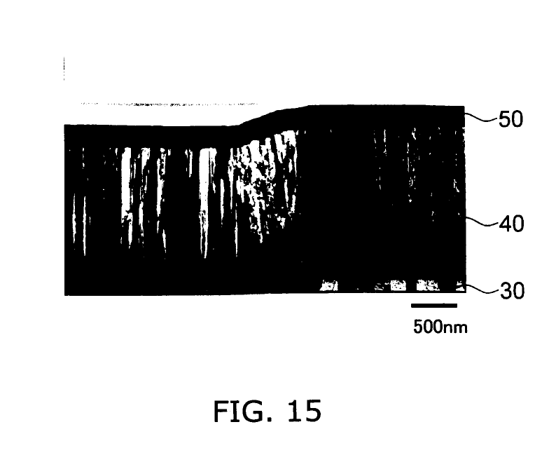

FIG. 15 is a TEM image showing a part of FBAR of the first embodiment.

It can be confirmed that the upper electrode 50 is provided all over the piezoelectric film 40. Moreover, it is seen that the piezoelectric film 40 sandwiched between the first film 30 and the upper electrode 50 has no cracks and fractures, according to the structure of the embodiment.

Subsequently, as shown in FIG. 16, the upper passivation layer 25 comprising SiN having a film thickness of 50 nanometers is deposited all over the device by the method of CVD (Chemical Vapor Deposition).

Then, contact holes are formed on the lower electrode 32 of the second tapered plane 36 and on the upper electrode 50 using dry etching such as RIE or the like, respectively.

As shown in FIG. 17, an Al film having a film thickness of 1000 nanometers is formed on the upper passivation layer 25 by the sputtering method. At this time, each electrode and the Al film are connected through contact holes. Then, patterning of the resist mask is performed. After that, wet etching is performed using, for example a mixed solution comprising phosphoric acid, acetic acid and nitric acid. This results in forming the extracting electrode 55 after selective removal of the Al film of the second tapered plane and the upper electrode.

After that, the back side of the Si substrate 10 is dry etched by a method of Deep-RIE (Deep-Reactive Ion Etching). Then, a Bosch mode of an ICP-RIE (Inductively Coupling Plasma-RIE) method may be used as the RIE method, which uses, for example sulfur hexafluoride (SF₆) and carbon fluoride (for example, C₄F₈) gases. In the Bosch mode, SF₆ gas plays a role to etch Si. C₄F₈ gas plays a role to form a polymer protective film on a Si side wall formed during etching. Therefore, alternative supply of these gases allows the Si substrate 10 to be etched substantially vertically, and to give the cavity 60 with a desired size.

This results in the removal of the Si substrate 10 under the first film 30. Moreover, the thermal oxidation film 15 is removed using, for example, solution of antimony fluoride. Then, the cavity 60 is formed under the first film 30. In this manner, the relevant part of FBAR 5 shown in FIG. 1 is completed.

On the contrary, a comparative example will be described below.

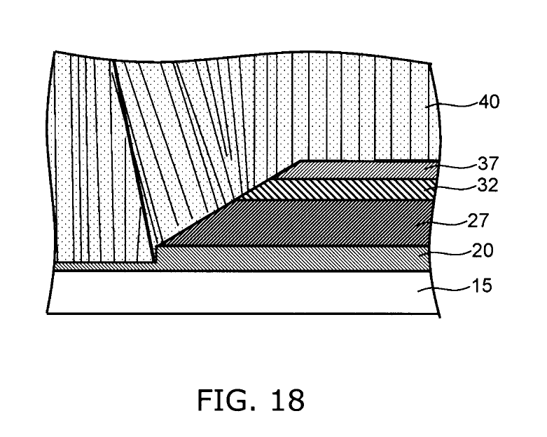

FIG. 18 is a schematic cross section showing the comparative example.

In the comparative example, for taper fabrication of the first film 30, the resist patterned by photolithography as well as in the first embodiment is baked at a high temperature. Then, the fabrication is performed by the RIE method, using the resist mask of which the end portion is fabricated into a tapered configuration. In the first embodiment, as the etching gas used in the RIE method, Cl₂ gas and BCl₃ gas are diluted with Ar and O₂ gas is added to them. However, in the comparative example, BCl₃ gas was increased, for example, about twice as in the first embodiment, furthermore etching was performed without addition of O₂ gas.

Consequently, angles between each film and the first tapered layer 35 are, for example, 80° for the lower passivation layer 20, 36° for the non-crystalline primary layer 27, 30° for the lower electrode 30 and 40° for the AlN film 37. That is to say, as the taper angle of the lower passivation layer 20 is substantially perpendicular to the major surface of the supporting substrate 10, growth directions of the piezoelectric film 40 run into each other. Therefore, it is seen that cracks and fractures are formed in the piezoelectric film 40 on the lower end 70.

Furthermore, on the first tapered plane 35, occurrence of cracks and fractures was also confirmed at the interface between the lower electrode 32 and the AlN film 37. This is because growth directions of the piezoelectric film 40 run into each other due to the taper angle of the lower electrode 32 being smaller than that of the AlN film 37.

The extracting electrode 55 was formed using wet etching fabrication on this sample as well as the first embodiment. However, the etchant infiltrates through from cracks and fractures of the lower end 70, and the lower electrode 32 was etched. Therefore, desirable characteristics were not obtained due to decrease of the resonant area. Moreover, occurrence of cracks and fractures near the back side of the first film 30 was observed.

### A Second Embodiment

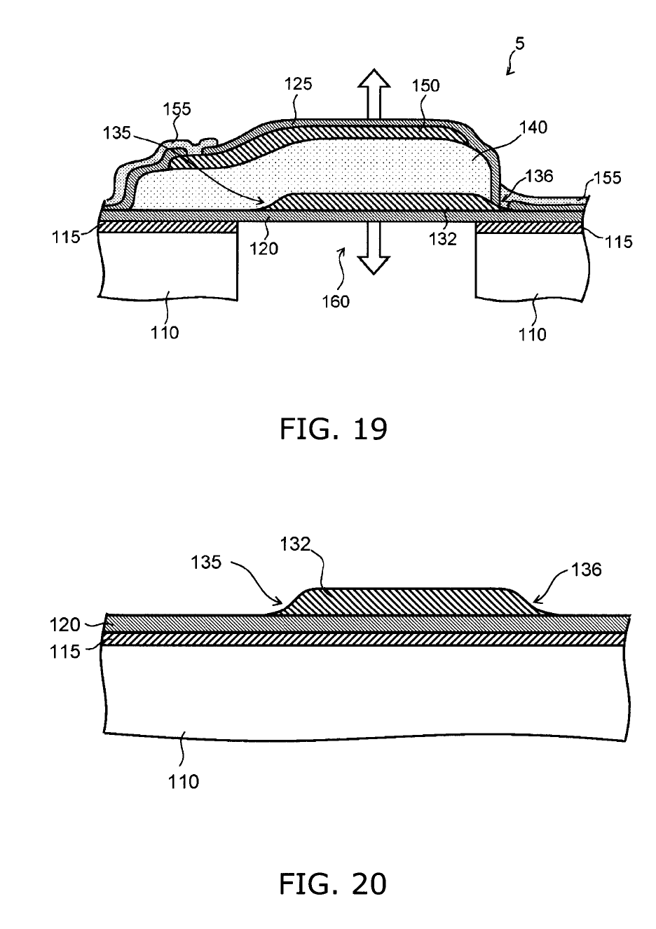

FIG. 19 is a schematic cross section showing an electronic device according to a second embodiment of the invention.

The electronic device of the embodiment is also FBAR (Thin Film Bulk Acoustic Resonator) 5. The FBAR 5 is formed on a supporting substrate 110 of Si. The supporting substrate 110 has a cavity 160. Then, all over the supporting substrate 110, a thermal oxidation (SiO₂) film 115 and a lower layer 120 of AlN are provided in this order. The lower layer 120 is crystalline oriented along a (0001) axis. A half width of a rocking curve of the (0001) axis by an X-ray diffraction method is about 10°. The first film is provided on the lower layer 120. In the embodiment, the first film is the lower electrode 132 of Mo.

The lower electrode 132 is in a trapezoid configuration narrowing toward an upper electrode 150. Moreover, both ends of the lower electrode 132 are provided with a first tapered plane 135 and a second tapered plane 136, respectively.

A piezoelectric film 140 made of, for example, AlN is provided over the lower electrode 132 selectively including the second tapered plane 136 toward the first tapered plane 135 and the lower layer 120 on the side of the first tapered plane 135. Furthermore, the piezoelectric film is not limited to being made of AlN, but can be made of ZnO and PZT. Over the piezoelectric film 140, the upper electrode 150 is provided. An upper passivation layer 125 and an extracting electrode 155 of Al are provided over the lower layer 120, the piezoelectric film 140, the upper electrode 150 and the second tapered plane 136. The upper electrode 150 and the lower electrode 132 have a selective contact hole, respectively. The upper electrode 150 and the lower electrode 132 are connected to the extracting electrode 155 through contact holes, respectively.

In the embodiment, lower ends 170 of the first and the second tapered planes 135, 136 are curved so that the slope of the tapered plane becomes gentle with getting close to the lower layer 120. This causes cracks and fractures hard to occur in the piezoelectric film 140 stacked on the end portion of the first tapered plane 135 of the lower electrode 132, and the excellent piezoelectric film 130 is obtained.

Hereinafter, a method of manufacturing FBAR 5 of the second embodiment shown in FIG. 19 will be described.

Here, FIG. 20˜FIG. 22 are process cross sections of a process of manufacturing FBAR of the second embodiment.

First, as shown in FIG. 20, a thermal oxidation film 115 comprising SiO₂ with a film thickness of about 300 nanometers is formed on a supporting substrate 110 of Si with a substrate thickness of about 600 microns. The lower layer 120 comprising AlN with a film thickness of about 30 nanometers is formed on the thermal oxidation film 115 using the sputtering method. The lower layer 120 is crystalline oriented to the (0001) axis. A Mo film with a film thickness, for example, of 300 nanometers is continuously deposited on the lower layer 120 using the sputtering method.

Moreover, after a patterning of a resist mask by photolithography, an etching is performed so that the lower electrode 132 is in a trapezoid configuration narrowing toward the direction facing the supporting substrate 110. This provides both ends of the lower electrode 132 with the first and the second tapered planes 135, 136.

At this time, mixed gases, for example, of carbon fluoride (for example CH₄) and O₂ gas can be used. Furthermore, the lower electrode 132 is etched while changing gradually a ratio CF₄/)O₂ in the mixed gas. Then a configuration with a tapered plane slope gradually curved with getting close to the lower layer 120 is formed. Moreover, AlN used for the lower layer 120 is resistant to the mixed gas, thereby plays a role as a stopper layer.

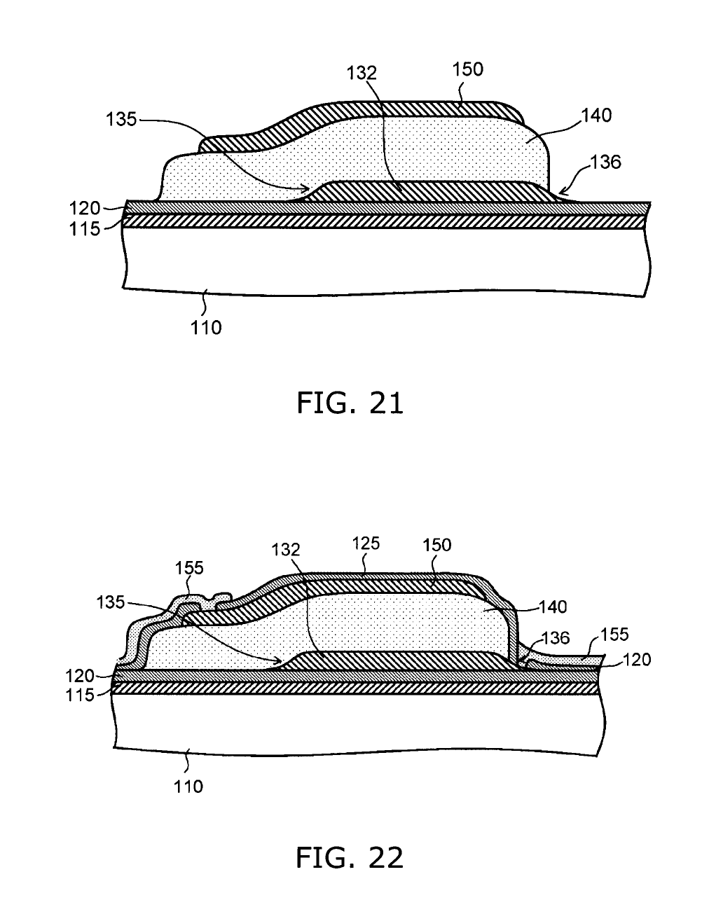

Subsequently, as shown in FIG. 21, the AlN film with a film thickness of 1.16 micrometers is deposited over the lower layer 120 and the lower electrode 132 using the sputtering method. Then, patterning of a resist mask is performed by photolithography. The AlN film on the lower layer is removed so as to enclose the lower electrode 132 by the RIE method using a mixed gas of Cl₂ and BCl₃. However, the AlN film on the second tapered plane 136 is removed for connection to the extracting electrode 155. Then, the piezoelectric film 140 is formed. In this manner, providing the AlN film of the lower layer 120 under the lower electrode 132 can improves the orientation of the lower electrode 132. Therefore, the orientation of the (0001) axis in the piezoelectric film 140 can be improved by setting the lower electrode 132 to be the substrate.

For example, it is difficult to form the highly oriented Mo film on the supporting substrate 110 of Si or SiO₂. Like the embodiment, the orientation of the Mo film is about 2.0°, even if the lower layer 120 of AlN with the thickness of about 30 nanometers is provided. Therefore, the orientation half width of the (0001) axis is about 2.0°, although the AlN film is formed on the Mo film. Moreover, Mo has a higher electrical resistance compared with Al of the first embodiment, then, causing Mo to be a thin film results in a higher serial resistance and a lower Q value.

However, the lower electrode 132 is made of a single layer film of Mo, and it needs to change a mixed ratio of etching gases during etching for processing it into a gentle and gradual slope configuration. But, it can be achieved by a relatively simple etching apparatus such as CDE (Chemical Dry Etching) or the like. Therefore, the FBAR characteristic of the Al lower electrode of the first embodiment is superior, but the process is simple and the same electrode is used for the upper and the lower ones, and from viewpoints of savings of a process chamber for sputtering film formation and sputtering targets, the second embodiment gives a more effective device structure.

The observation of the first tapered portion 135 of the lower electrode 132 revealed that the angle of the upper end 180 of the first tapered portion 135 is 145°. Moreover, it was confirmed that cracks and fractures do not occur in the piezoelectric film 140 on the lower end 170 and the upper end 180.

Furthermore, a curvature radius of each tapered plane 135 partitioned off parallel to the supporting substrate 110, for example, every 10 nanometers was measured. As a result, the minimum value Rmin of the curvature was 1.8 micrometers. This value is larger than 1.16 micrometers of the film thickness of the piezoelectric film 140. Therefore, it is revealed that no cracks and fractures occur in the piezoelectric film 140 on the first tapered plane 135, as described previously in FIG. 3.

Furthermore, partitioning off into 5 layers is performed every 65 nanometers of particle size of the piezoelectric film 140 parallel to the supporting substrate 110. For example, they are four layers from the lower layer 120 toward to the upper electrode 150 and the other residual one layer. Then, angles between each layer and the first tapered plane 135 (θ₁, θ₂, θ₃, θ₄, θ₅) were measured. Angles were 12° for θ₁, 18° for θ₂, 23° for θ₃, 28° for θ₄ and 35° for θ₅, respectively toward to the upper electrode 150. It is revealed that the maximum angle is θ₅ and the angle increases from θ1 to θ5 in this order (θ₁<θ₂<θ₃<θ₄<θ₅). The relation like this causes the lower end 170 of the first tapered plane 135 to be in a configuration that the slope becomes small with getting close to the lower layer 120. Then, cracks and fractures can be suppressed in the piezoelectric film 140.

Thereafter, the Mo film with a film thickness of 300 nanometers is deposited on the piezoelectric film 140 using the sputtering method. Then, the selective resist patterning is performed by photolithography. Moreover, the upper electrode 150 is formed by etching using the CDE (Chemical Dry Etching) method.

Subsequently, as shown in FIG. 22, the upper passivation layer 121 is formed by depositing the SiN film with a film thickness of 50 nanometers all over the device using the sputtering method. Thereafter, contact holes are formed in the upper electrode 150 on the side of the second tapered plane 136 and on the side of the first tapered plane 135.

Furthermore, the Al film with a film thickness of 1000 nanometers is deposited on the upper passivation layer 125 using the sputtering method. Patterning of the resist mask is performed by photolithography. Thereafter, wet etching is performed using a mixed solution including, for example phosphoric acid, acetic acid and nitric acid. This results in formation of the extracting electrode 155 by selective removal of the Al film on the lower electrode 132 and the upper electrode 150. The extracting electrode 155 is connected to the lower electrode 132 and the upper electrode 150 through contact holes, respectively.

Furthermore, as shown in FIG. 19, the back side of the supporting substrate 110 is etched by a dry process using the method of Deep-RIE (Deep Reactive Ion Etching). Thus, the supporting substrate 110 under the lower electrode 132 is removed. Moreover, the thermal oxidation film 115 is removed using, for example ammonium solution. Then, a cavity 160 is formed on the back side of the lower electrode 132. In this way, FBAR 5 of FIG. 19 is completed.

On the contrary, a comparative example of the second embodiment will be described below.

First, a first comparative example is described.

That is to say, the basic structure of the comparative example is substantially the same as the second embodiment. However, the first and the second tapered planes 135, 136 were formed by a process of both ends of the lower electrode 132 using a mixed gas including CF4 gas with a high concentration. In the process, the composition of the mixed gas was kept constant.

As a result, the first tapered plane 135 came into a flat configuration as described previously in FIG. 4. Angles at the lower end 170 and the upper end 180 of the tapered portion (see FIG. 19) were 25° and 155°, respectively. It was confirmed that cracks and fractures originating from the lower end 170 of the first tapered plane 135 occur in the piezoelectric film 140 on the tapered portion.

Next, a second comparative example is described.

In the comparative example, the formation of the first and the second tapered planes 135, 136 of the lower electrode 132 was performed by wet etching using mixed solution comprising acetic acid, phosphoric acid and nitric acid. The use of this mixed solution allows isotropic etching to be achieved.

At the lower end 170 of the first and the second tapered planes 135, 136, the slope of the tapered plane becomes gentle with getting close to the lower layer 120.

However, an angle at the upper end 180 of the first tapered plane 135 was 130°. Furthermore, a curvature radius of each tapered plane 135 partitioned off parallel to the lower layer 120, for example every 10 nanometers was measured. As a result, the minimum value Rmin of the curvature was 1.75 micrometers and larger than 1.16 micrometers of the film thickness of the piezoelectric film 140. Therefore, in the comparative example, the substantially continuous piezoelectric film 140 was obtained at the lower end 170 of the first tapered plane 135 or on the tapered plane 135, but it was revealed that cracks and fractures occur in the piezoelectric film 140, originating from the upper end 180 of the first tapered plane 135.

Next, a third comparative example is described.

In the comparative example, for the formation of the first and the second tapered planes 135, 136 of the lower electrode 132, mixed gas comprising CF₄ gas and O₂ gas was used as etching gas. In the process, etching was performed, while the CF₄/O₂ ratio in the mixed gas was varied in three steps different from a consecutive change like the second embodiment. For example, they are the first gas mixed ratio and the last mixed ratio in the second embodiment, and the intermediate ratio between them.

This result allowed the curved configuration to be obtained at the lower end 170 of the first and the second tapered planes 135, 136, which the slope of the tapered plane becomes gentle with getting close to the lower layer 120. Moreover, the angle at the upper end 180 of the first tapered plane 135 was 140°. However, a curvature radius of each tapered plane 35 partitioned off parallel to the lower layer 120, for example every 10 nanometers was measured. As a result, it was revealed that the minimum value Rmin of the curvature was 1.0 micrometers and smaller than 1.16 micrometers of the film thickness of the piezoelectric film 140. Thus, cracks occurred in the piezoelectric film 140. This is because that the curved configuration of the tapered plane became sharp and the curvature radius became small due to the three steps change of gas ratio during etching the lower electrode 132, in comparison with the consecutive change.

Embodiments of the invention have been described with reference to embodiments and comparative examples.

A frequency filter can be manufactured by combining plural FBARs with different resonant frequency in parallel or in series using FBAR 5 such as FBAR 5 shown in the first and the second embodiment. For example, a frequency filter of 2 GHz zone is obtained by lowering the resonant frequency of the parallel FBAR by about 70 MHz than the resonant frequency of the serial FBAR.

It can be formed on the supporting substrate 110 of semiconductor as with the first and the second embodiments. Therefore, for example, it is also easy to make an RF filter to be monolithic. Moreover, according to the embodiment, an excellent characteristic and high-efficiency FBAR filter 100 is supplied.

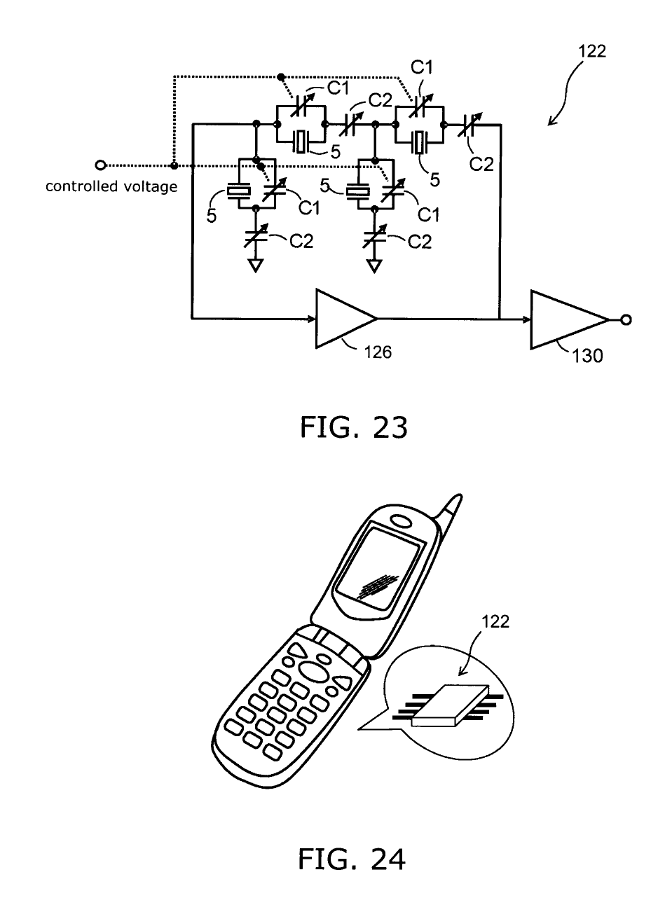

FIG. 23 is a circuit diagram of a voltage controlled oscillator mounting an electronic device according to the embodiment.

The Voltage Controlled Oscillator (VCO) 122 has FBAR 5, an amplifier 126, a buffer amplifier 130 and capacitance variable capacitors C1, C2. Here, the feedback of frequency components passing through the FBAR filter 100 is made to the amplifier 126, and output signal is taken. Thereby, it allows the frequency adjustment to be achieved.

The VCO 122 like this contributes to downsizing due to its simple constitution. For example, it is mounted on a cellular phone as shown in FIG. 4 and information terminal devices such as PDA and a notebook PC not shown.

Embodiments of the invention have been described with reference to examples. However, the invention is not limited to these examples. For example, even if any shape except a square, that is, a quadrangle such as a rectangle, a triangle, a polygon and an inequilateral polygon or the like are used for the planar shape of oscillating portion in FBAR of the embodiment, more of the same effects as the embodiment are obtained.

Moreover, in the embodiment, silicon was used for the supporting substrate material, but for example, gallium arsenide (GaAs), indium phosphide (InP), quartz, glass or other materials such as plastic having heat resistance of about 200° C. can also be used.

Furthermore, FBAR was described as an electronic device of the invention, but the invention is not limited to this, and more of the same working effects are obtained from a similar embodiment about other electronic devices such as MEMS device.

The material, composition, shape, pattern and manufacturing process of elements constituting the electronic device of the invention that are adapted by those skilled in the art are also encompassed within the scope of the invention as long as they include the features of the invention.

1. An electronic device comprising:
a substrate;
a first film provided on a major surface of the substrate and having at least one end surface; and
a crystalline second film covering at least a part of the end surface and provided on the first film and the substrate,
the end surface having an inclined surface which is inclined to the major surface of the substrate, and
the inclined surface having a curved surface whose slope becomes gentle with getting closer to the substrate.

2. The electronic device according to claim 1, wherein the curved surface is a concave surface.

3. The electronic device according to claim 1, wherein the inclined surface has a convex portion protruding toward the second film.

4. The electronic device according to claim 1, wherein the second film is a polycrystal which is oriented in a thickness direction.

5. The electronic device according to claim 1, further comprising an upper electrode provided on the second film, wherein
the substrate has a cavity,
the first film forms a lower electrode, and
the second film is made of one selected from the group consisting of aluminum nitride (AlN), zinc oxide (ZnO) and lead zirconate titanate (PZT).

6. The electronic device according to claim 1, wherein a curvature radius of the inclined surface is larger than a thickness of the second film.

7. The electronic device according to claim 1, wherein an angle at an upper end of the inclined surface is substantially larger than 135°.

8. An electronic device comprising:
a substrate;
a first film provided on a major surface of the substrate and having at least one end surface;
a crystalline second film covering at least a part of the end surface and provided on the first film and the substrate; and
an upper electrode provided on the second film,
the end surface having an inclined surface which is inclined to the major surface of the substrate, and
the inclined surface having a curved part at its upper end, a slope of the curved part being gentle with getting closer to the upper electrode.

9. The electronic device according to claim 8, wherein the inclined surface has a concave surface which is provided under the upper end.

10. The electronic device according to claim 8, wherein the second film is a polycrystal which is oriented in a thickness direction.

11. The electronic device according to claim 8, wherein
the substrate has a cavity,
the first film forms a lower electrode, and
the second film is made of one selected from the group consisting of aluminum nitride (AlN), zinc oxide (ZnO) and lead zirconate titanate (PZT).

12. The electronic device according to claim 8, wherein a curvature radius of the inclined surface is larger than a thickness of the second film.

13. The electronic device according to claim 8, wherein the inclined surface having a curved surface whose slope becomes gentle with getting closer to the substrate.

14. An electronic device comprising:
a substrate;
a first film provided on a major surface of the substrate and having at least one end surface; and
a crystalline second film covering at least a part of the end surface and provided on the first film and the substrate,
the end surface having an inclined surface which is inclined to the major surface of the substrate, and
the inclined surface having a convex portion protruding toward the second film, the convex portion being provided between an upper end and lower end of the inclined surface.

15. The electronic device according to claim 14, wherein an angle of a slope of the inclined surface has a relative maximum.

16. The electronic device according to claim 14, wherein a concave surface is provided under the convex portion on the inclined surface.

17. The electronic device according to claim 14, wherein the second film is a polycrystal which is oriented in a thickness direction.

18. The electronic device according to claim 14, wherein an angle at an upper end of the inclined surface is substantially larger than 135°.

19. The electronic device according to claim 14, wherein a curvature radius of the inclined surface is larger than a thickness of the second film.

20. The electronic device according to claim 14, wherein
the substrate has a cavity,
the first film forms a lower electrode, and
the second film is made of one selected from the group consisting of aluminum nitride (AlN), zinc oxide (ZnO) and lead zirconate titanate (PZT).
